(19) United States
(12) Patent Application Publication
(10) Pub. No.: US 2012/0006581 A1
(43) Pub. Date: Jan. 12, 2012

(54) CABLE ORGANISER

(75) Inventor: David Cross, New South Wales (AU)

(73) Assignee: BIRALEE INVESTMENTS PTY LIMITED, Sydney (AU)

(21) Appl. No.: 13/143,528

(22) PCT Filed: Jan. 5, 2010
(86) PCT No.: PCT/AU2010/000002

§ 371 Date: Sep. 26, 2011

(30) Foreign Application Priority Data
Jan. 7, 2009 (AU) 2009900059

(51) Int. Cl. H05K 7/00; H01R 24/62

(52) U.S. Cl. 174/135; 439/676

(57) ABSTRACT

The present invention relates to a cable organiser, in particular to a cable organiser used to secure headphones for use with an electronic device. In one aspect the invention relates to a cable organiser for use with an electronic device, the electronic device including a jack socket for receiving a cable jack from which a cable extends, the cable organiser including a body, the body having a positioning means for enabling the cable organiser to be detachably mounted to the electronic device via the jack socket; and cable retaining means in a position radially offset from the positioning means, the cable retaining means being configured to releasably retain the cable. In another aspect the invention includes first and second cable restraining means. In another aspect of the invention the cable organiser and the housing of the cable jack are integrally formed.

### FIELD OF THE INVENTION

The present invention relates to a cable organiser, in particular to a cable organiser used to secure headphones for use with an electronic device.

### BACKGROUND OF THE INVENTION

When using portable electronic devices it is often desirable to have a method of organising cables associated with the devices. For example, for personal media devices with headphones it may be desirable to have a way to wrap up the headphone cable neatly when the personal media device is not in use.

One way of handling headphone cables is to wrap them around a loose-standing cable organiser. One disadvantage of this type of organiser is that it is separated from the electronic device being used and is prone to being mislaid. Some cable organisers can cause cable damage if the cables are wrapped tightly around them.

Reference to any prior art in the specification is not, and should not be taken as, an acknowledgment or any form of suggestion that this prior art forms part of the common general knowledge in Australia or any other jurisdiction or that this prior art could reasonably be expected to be ascertained, understood and regarded as relevant by a person skilled in the art.

### SUMMARY OF THE INVENTION

In one aspect the invention relates to a cable organiser for use with an electronic device, the electronic device including a jack socket for receiving a cable jack from which a cable extends, the cable organiser including a body, the body having a positioning means for enabling the cable organiser to be detachably mounted to the electronic device via the jack socket; and cable retaining means in a position radially offset from the positioning means, the cable retaining means being configured to releasably retain the cable.

In another aspect of the invention the body of the cable organiser includes a base and a cover engaged with the base.

In another aspect the invention includes first and second cable restraining means. The cable restraining means can be adapted so that the first cable restraining means is adapted to receive a single cable and the second cable restraining means is adapted to receive two cables.

In another aspect of the invention, the second cable restraining means is offset from a diametric axis of the cable organiser that crosses the position of the first cable restraining mean.

In another aspect of the invention the cable organiser includes a stabilising means for preventing rotational movement of the cable organiser relative to the electronic device when the cable organiser is connect to the device.

In another aspect of the invention the cable organiser and the housing of the cable jack are integrally formed.

As used herein, except where the context requires otherwise, the term “comprise” and variations of the term, such as “comprising”, “comprises” and “comprised”, are not intended to exclude further additives, components, integers or steps.

### BRIEF DESCRIPTION OF THE DRAWINGS

The invention may best be understood by referring to the following description and accompanying drawings that are used to illustrate embodiments of the invention by way of non-limiting example only.

In the drawings:

FIG. 1 is an exploded perspective view of a first embodiment of a cable organiser of the invention.

FIG. 2 is a detailed perspective view of a base forming part of the cable organiser of FIG. 1.

FIG. 3 is a further exploded perspective view of the cable organiser of FIG. 1.

FIG. 4 is a perspective view of the cable organiser of FIG. 1 when it is assembled.

FIG. 5 is a plan view of the assembled cable organiser of FIG. 4.

FIG. 6A is a side view of the cable organiser of FIG. 1, assembled and mounted in position.

FIG. 6B is a view of the section A-A of FIG. 6A.

FIGS. 7A and B show two stages of the cable organiser being used to secure a cable by wrapping it around an electronic device.

FIG. 8 shows an alternative wrapping method.

FIG. 9A is a side view of a second embodiment of a cable organiser of the invention.

FIG. 9B is a front view of a second embodiment of a cable organiser of the invention.

FIG. 9C is a view of the section B-B of FIG. 9B.

FIG. 10 is a bottom perspective view of the second embodiment of the cable organiser of FIGS. 9A-C.

FIG. 11A is an under plan view of the cable organiser of FIGS. 9A-C.

FIG. 11B is a view of section C-C of FIG. 11A

FIG. 12A is a top view of a third embodiment of a cable organiser of the invention

FIG. 12B is a side perspective view of the cable organiser of FIG. 12A.

FIG. 13 is a fourth embodiment of a cable organiser of the invention.

FIG. 14 is a fifth embodiment of a cable organiser of the invention.

FIGS. 15A and B show a sixth embodiment of a cable organiser of the invention.

### DETAILED DESCRIPTION OF THE EMBODIMENTS

This detailed description refers to specific embodiments of the invention. Those embodiments are used to illustrate the principles of the invention, and other embodiments can be utilised without departing from the scope of the present invention.

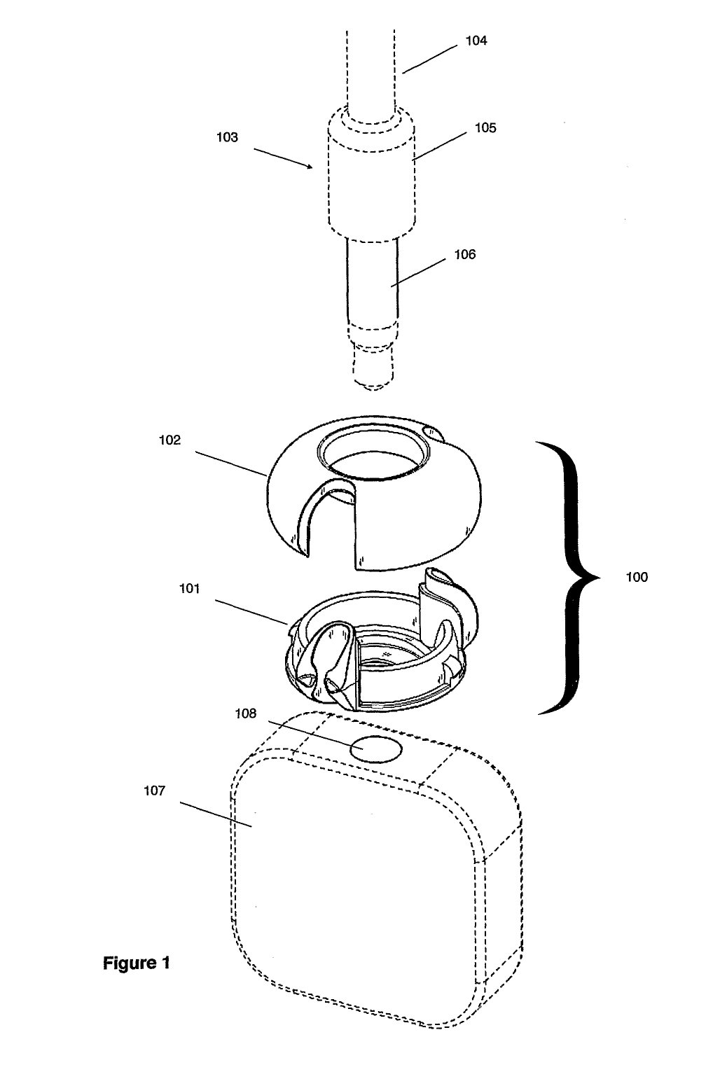

The present invention is directed to a cable organiser that is compact and easy to use with an electronic device, for example with a portable media device. The cable organiser is retained in position by the cable jack of the electronic device. FIG. 1 illustrates a first embodiment of a cable organiser 100. The cable organiser 100 consists of a base 101 and a cover 102. A cable jack 103 connected to a cable 104 and consisting of a jack housing 105 and a jack plug 106 is passed through the centre of the base 101 and cover 102 to affix the organiser 100 to an electronic device 107, such as a personal media device, when the jack plug 106 is inserted into the jack socket 108.

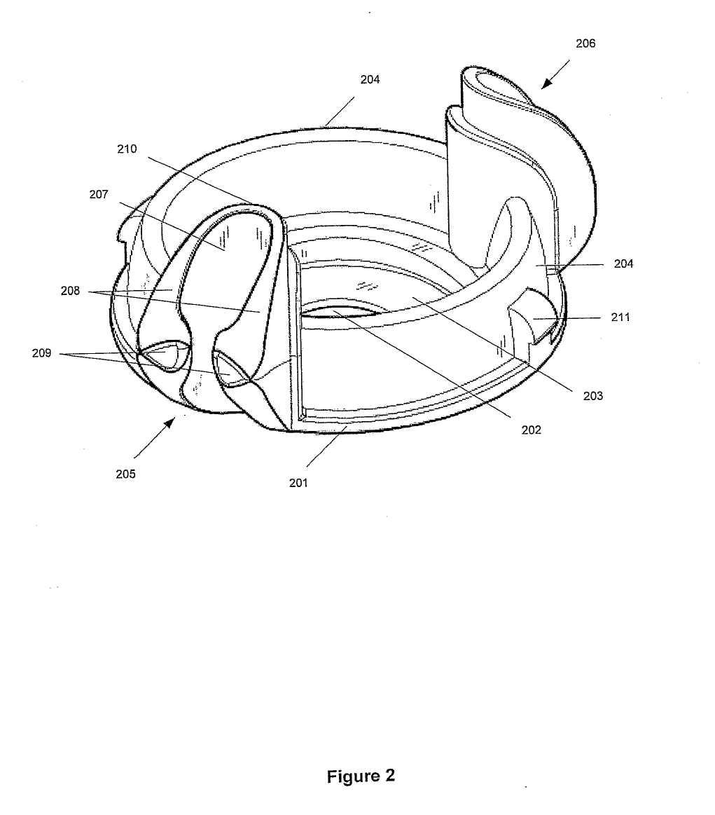

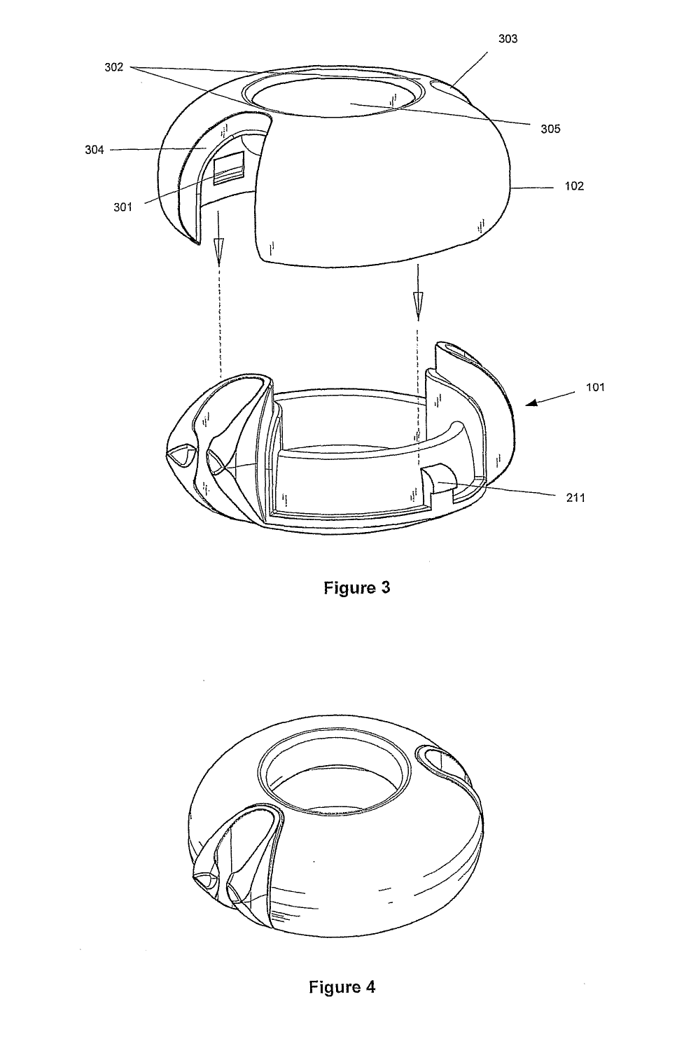

FIG. 2 shows a detailed view of the base 101 of the cable organiser. The base is hub-shaped, consisting of a base portion 201 that has a central aperture 202 in the base wall 203. The base portion supports arcuate walls 204 that extend between cable restraining means 205 and 206. The cable restraining means 205, 206 each comprise a channel formation 207 configured to accommodate one or more cables, including side walls 208, re-entrant portions 209 defining a narrowed entrance to each channel, and a bight portion 210. In this embodiment the channel formations 207 are positioned to be vertical with respect to the cable organiser, in other words to be parallel to the longitudinal axis of the cable jack that fits through the centre of the cable organiser. The two cable restraining moans 205, 206 shown are shaped differently to accommodate different sized cables, but they can alternatively be the same size, and can also be any suitable size for the relevant type or number of cables required to be secured. A clip 211 is used to secure the cover 102 to the base 101 and is described below with reference to FIG. 3.

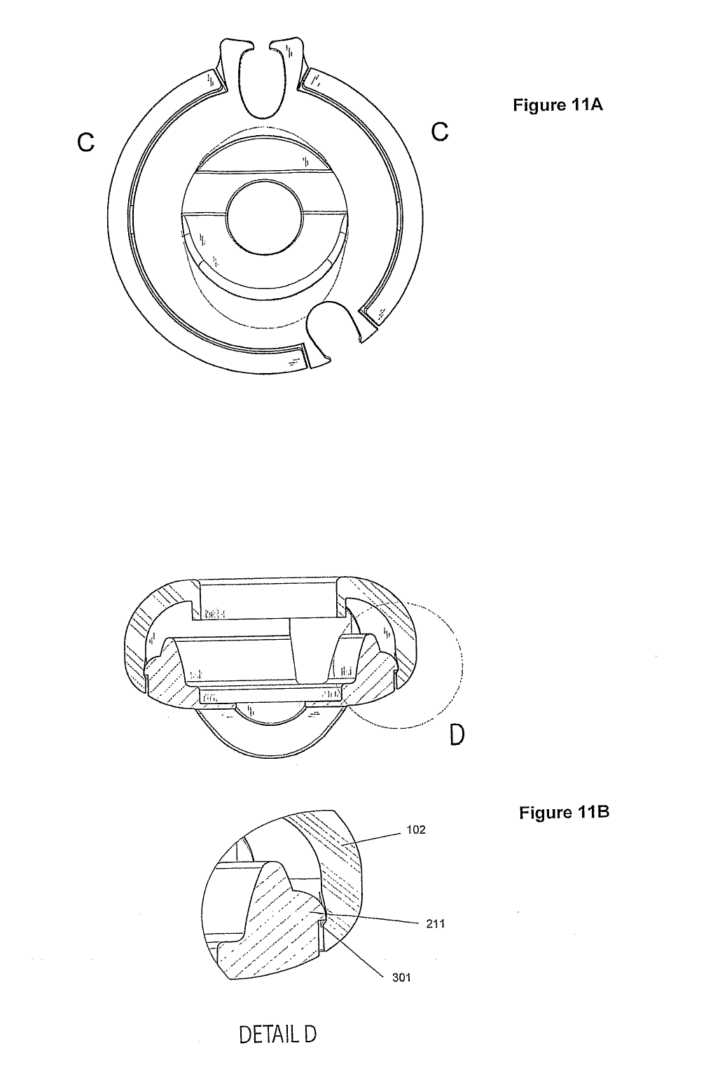

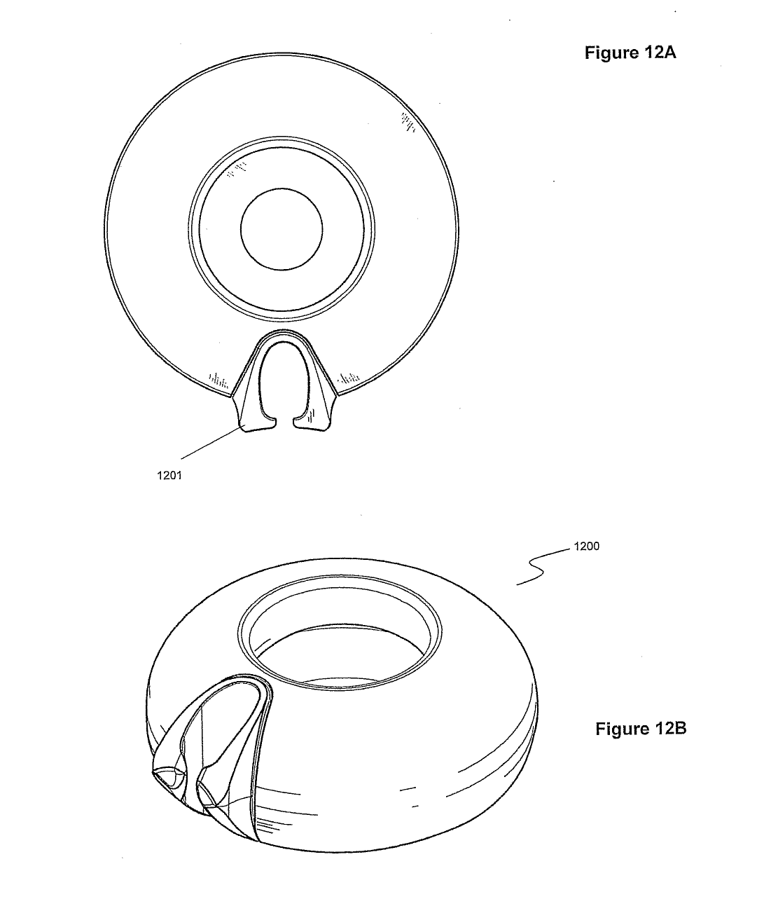

FIG. 3 shows that the cover 102 fits over the base 101 of the organiser and is shaped to fit snugly against the base 101 by including, for example, cut-outs 303, 304 to accommodate the cable restraining means 205, 206. The cover 102 also has a central aperture 305 substantially aligned with the aperture of the base 202 to allow the cable jack 103 to be inserted through the aperture 305. The cover 102 may be made of a flexible material such as a thermoplastic polymer like polypropylene, and flexes as it is pushed down over the body 101. The cover 102 may also be made of a rigid material such as acrylonitrile butadiene styrene (ABS). The flexure points 302 contribute to the flexibility required to push the cover 102 over the base 101. The clip on the base 211 is used to hold the cover 102 in place as it interacts with a recess 301 on the inside of the cover 102. This is described in more detail below with reference to FIG. 11.

FIG. 4 thews an assembled cable organiser with the cover 102 secured to the base 101.

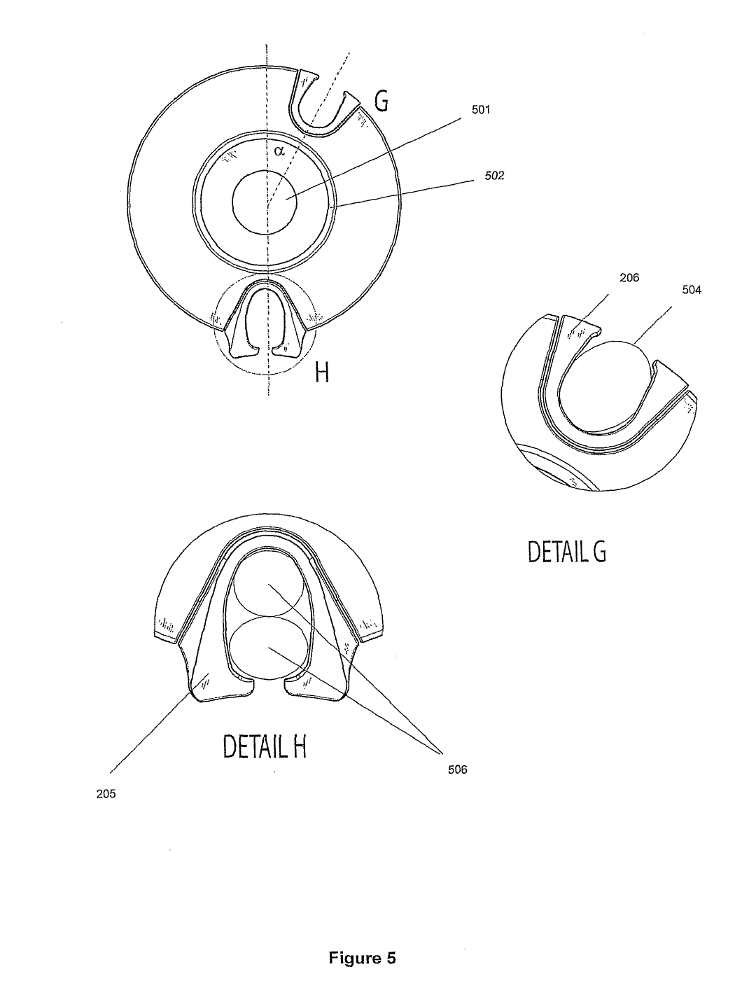

Referring to FIG. 5, the radius of the aperture 501 through which the jack plug 106 projects is smaller than the radius of the inner wall 502 of the arcuate walls 204. This configuration contributes to the jack holding the cable organiser down against the media device when the jack is plugged into the jack socket of the media device. This functionality can also be achieved in a different way, for example by attaching the organiser to the jack with a clasp. If a headphone adapter is used, the cable organiser can fit between the headphone adapter and the headphone jack, or alternatively attach to the headphone adapter with a clasp or some other mechanism.

FIG. 5 also provides more details of the cable restraining means 205, 206. The smaller one 206 is shaped to accept one cable 504. This size is typical of the configuration of headphone cables closer to the headphone jack. The larger one 205 is shaped to accept two cables 506. These cables typically have a smaller diameter than the single cable that fits into the smaller cable restraining, means 206, and these cables are typically the headphone cables towards the earphones, also called the earphone cables. In this example the cable restraining means 205, 206 sit on either side of the aperture 501 through the centre of the organiser which is used to position and attach the organiser to an electronic device by inserting a cable jack through the aperture and then into the electronic device. The two cable restraining means 205, 206 do not, however, lie on the same diametric axis through the centre of the cable organiser. Cable restraining means 206 is offset from the diametric axis that crosses the position of cable restraining means 205 by angle α. This offset can improve the cable winding characteristics offered by the cable organiser. The cable organiser is used so that the larger cable restraining means 205 sits towards the front of the electronic device. In this description, the front of the device is considered to be the side with the primary user interface that includes a display and other input-output functionality. The smaller cable restraining, mean 206 sits towards the back of the electronic, device, on the opposite side to the front.

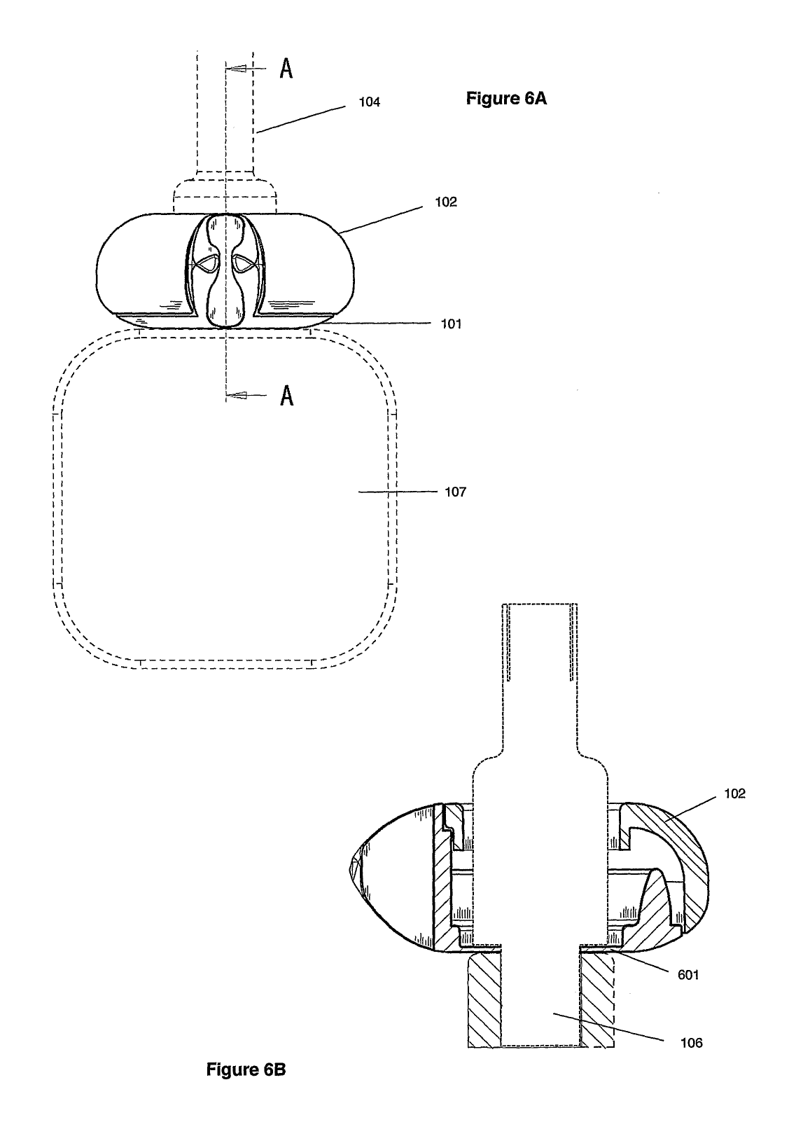

FIG. 6A shows a cable organiser, assembled and mounted in position. FIG. 6B shows the section A-A of FIG. 6A. The inner surface 601 of the inner-most part of the base lies against the jack plug and provides a friction fit. The friction fit will result in the cable organiser staying with the cable jack if the jack is removed from the electronic device.

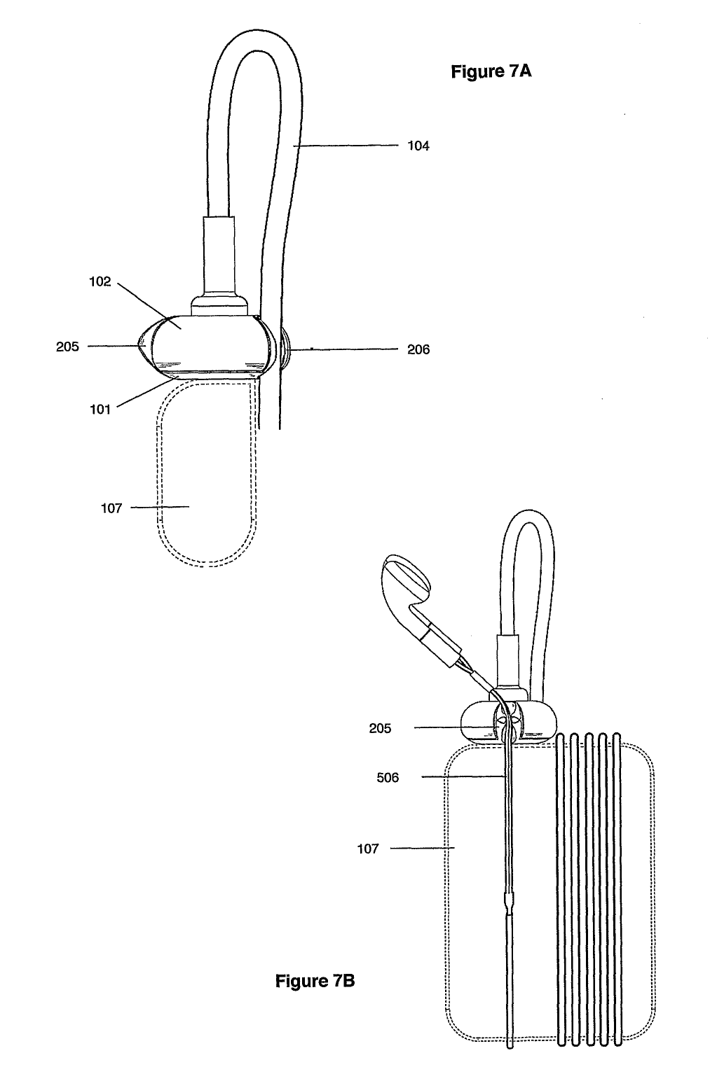

FIG. 7 illustrates how the cable organiser is used. FIG. 7A shows how the smaller cable restraining means 206 at the back provides a locking point to pivot the cable 104 when winding it around the personal media device 107. It is also possible to incorporate a locking point with a different configuration for assisting the way the cable is wound around the electronic device, for example by guiding the cable in a certain direction or at a certain angle. It is possible to have a cable organiser that does not have this first cable restraining means 206, but only a second or final one 205.

FIG. 7B shows that once the cable 104 has been wound around the media device, the earphone cables 506 are secured by the front cable, restraining means 205. In this figure, the cable has been wound around the length of the personal media device 107.

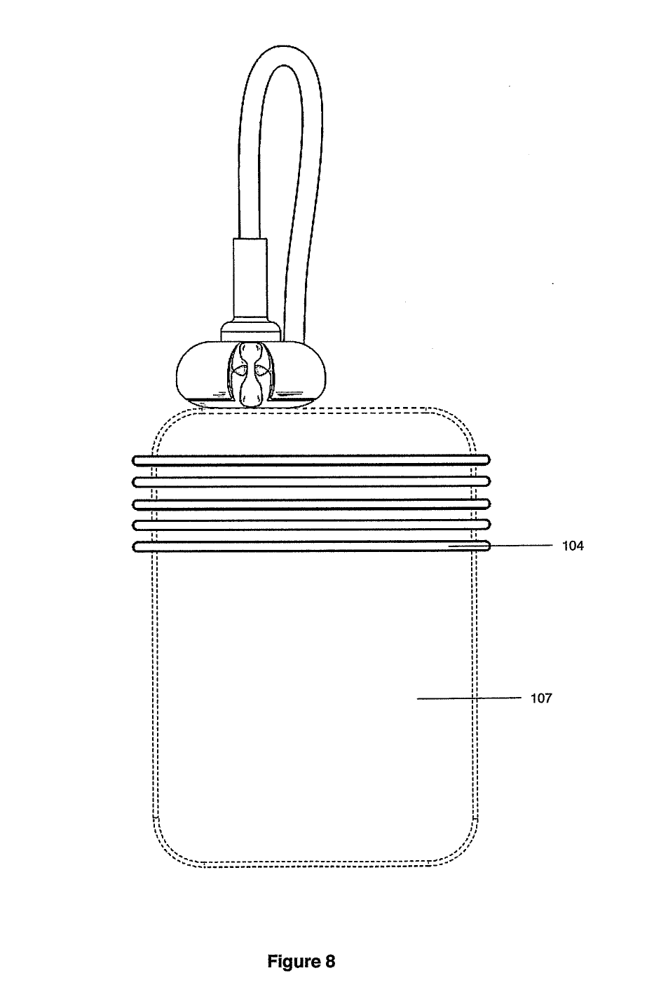

FIG. 8 shows that the cable 104 can also be wound around the width of the personal media device 107.

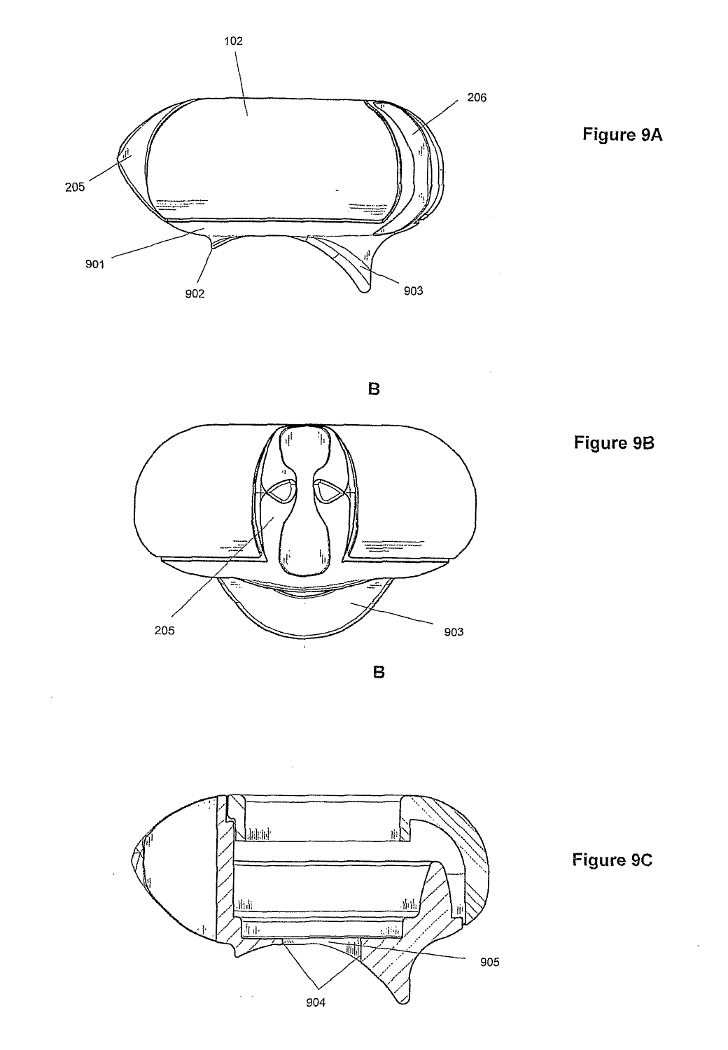

FIG. 9 shows a second embodiment of the cable organiser of the invention that includes a stabilising means by including a shaped base 901, shaped so that the organiser can sit snugly against the surface of a portable media device. The shaped base 901 includes two flanges. When used with a portable media device, the smaller flange 902 will sit to the front of the electronic device, and the larger flange 903 will sit towards the back of the device. In this example the base of the cable organiser and the flanges are integrally formed, although they can alternatively be separate components attached to one another. The cable organiser is stabilised because the profile of the stabilising means complements the shape of the electronic device thereby preventing rotational movement of the cable organiser relative to the electronic device. The sizes and shapes of the flanges of the stabilising means may suit a specific device or range of devices.

The stabilising means lies against the outside surface of the electronic device. It is also possible to incorporate stabilising means that insert at least partially into any suitable part of the electronic device, such as a socket, including a headphone jack socket, data sharing ports, or a charger socket. It is also possible to incorporate stabilising means that do not cooperate with the electronic device on both the front and the back side of the device, but only on one side. It is also possible to incorporate stabilising means that work with a different type of stabilising mechanism, for example through a clip or a friction fit around the cable jack or the jack housing.

In this embodiment there is also a friction fit surface 904 around the aperture 905 through the centre of the organiser base 901.

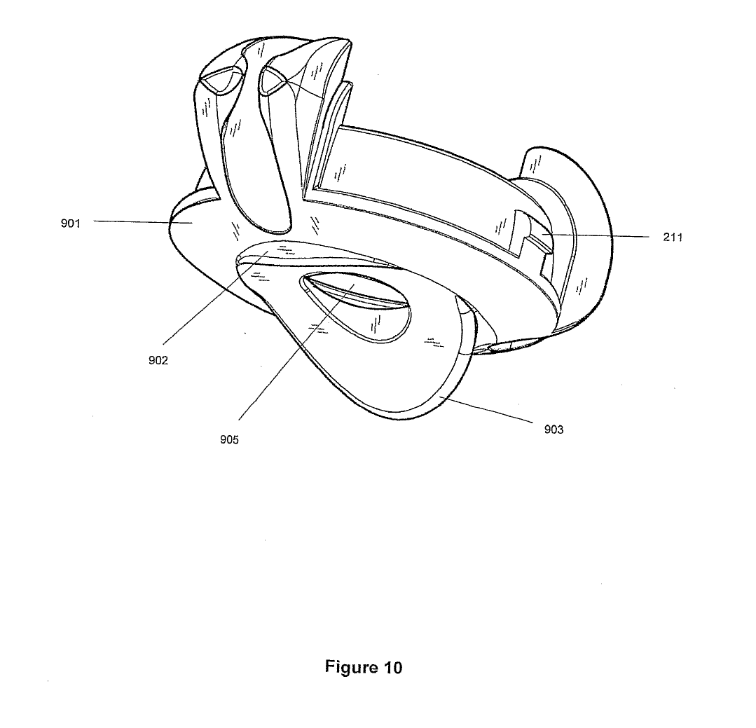

FIG. 10 shows a perspective view of the shaped base of this embodiment from below.

FIG. 11 provides a more detailed view of the mechanism that can be used to secure the cover to the base, which in this embodiment is similar to the first embodiment described with reference to FIG. 3 above. The clip 211 is rigid and the cover 102 with the recess 301 that accepts the clip is flexible. In order to lock the cover down, the flexible cover is simply pushed down over the base until the clip slides into the recess. In order to release the cover from the base, the flexible cover is bent, aided by flexure points 302, until the clip 211 is no longer in contact with the recess 301 and the cover can be lifted off. The cover can also be attached to the base with a different internally extruded locking mechanism, or can simply be pulled over the base and kept in place through friction. It is possible to have an embodiment that includes securing clips on the cover and none on the base. It is also possible for the base and the cover to be formed integrally, or to attach in any other way that may include sticking, screwing, locking or clipping mechanisms.

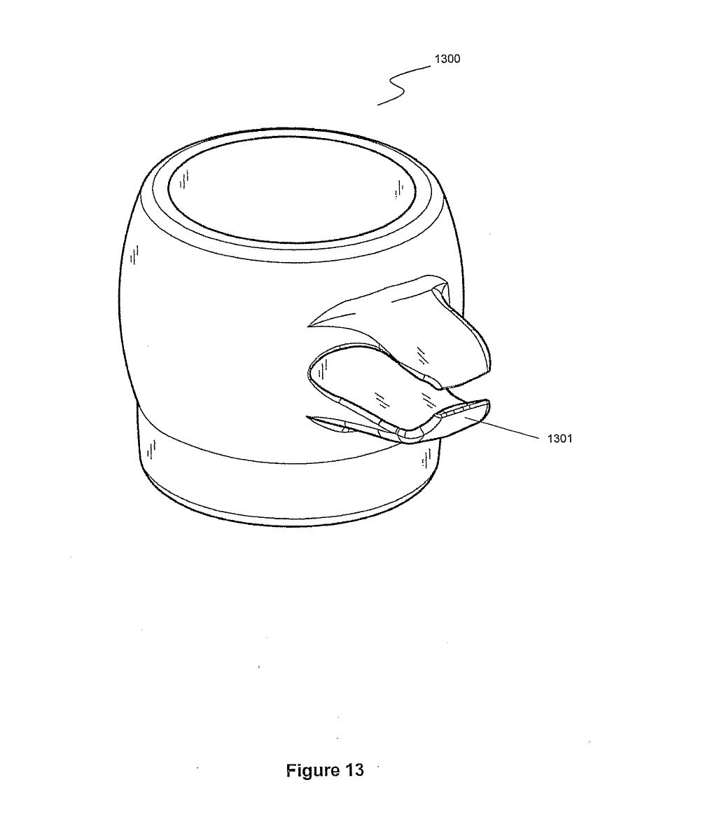

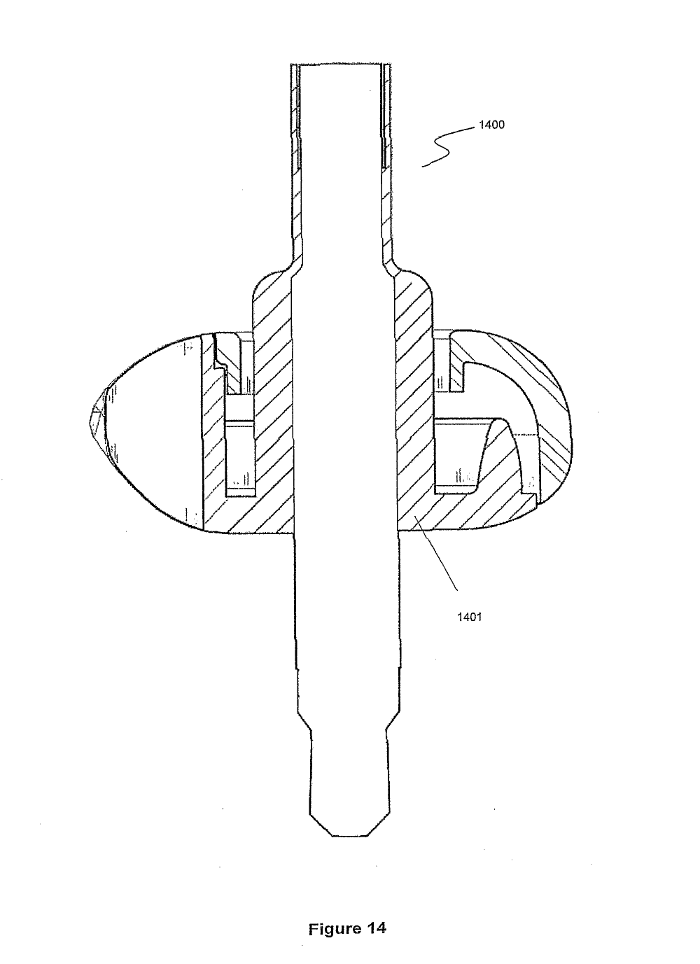

FIG. 12 shows a third embodiment 1200 of the invention that includes only one cable restraining means 1201. FIG. 13 shows a fourth embodiment 1300 that also has only one cable restraining means 1301, this time oriented horizontally. The number, orientation, and size of the cable restraining means are all variable.

FIG. 14 shows a section through an embodiment 1400 of the invention where the base of a cable organiser 1401 is integrally formed with the jack housing. The organiser can also be integrally formed with the jack housing of a headphone cable adapter. It is also possible to integrally form the cover, the base and the jack housing.

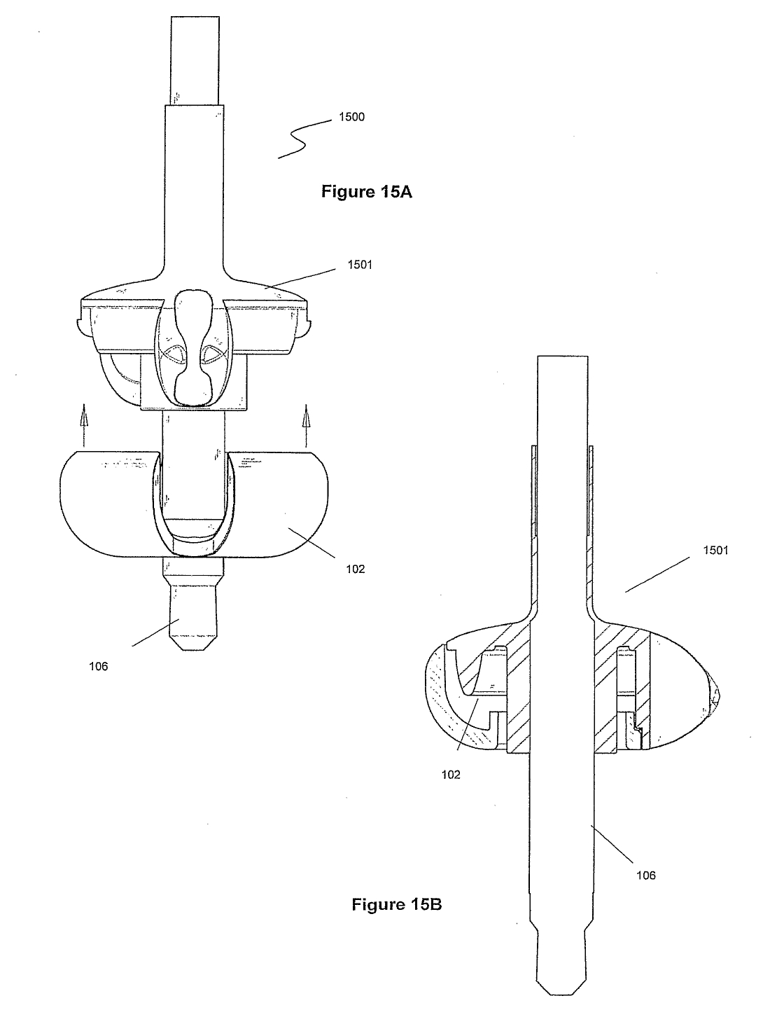

FIG. 15A shows an embodiment 1500 of the invention where the base of the cable organiser 1501 is integrally formed with the jack housing, and is oriented with the base towards the cable. The cover 102 is placed over the base 1501, and lies towards the electronic device 107 when the jack is inserted into the jack socket 108. FIG. 15B shows a section through the embodiment 1500 of FIG. 15A.

The shape of the organiser, whether it consists of only a base portion, or of a base together with a cover, can be a torus or doughnut shape. The organiser can also be any other toroidal shape as the plane curve forming the toroid need not be circular. The shape of the organiser need not be toroidal either, and can be any symmetrical or asymmetrical shape. The organiser can be flexible, rigid, or a combination. The organiser can be various shapes or colours, and can be any kind of decorative representation. When including a cover, the cover can be various shapes or colours, and can be any kind of decorative representation.

It will be understood that the invention disclosed and defined in this specification extends to all alternative combinations of two or more of the individual features mentioned or evident from the text or drawings. All of these different combinations constitute various alternative aspects of the invention.

1. A cable organiser for use with an electronic device, the electronic device including a jack socket for receiving a cable jack from which a cable extends, the cable organiser comprising a body, the body having
a positioning means for enabling the cable organiser to be detachably mounted to the electronic device via the jack socket; and
at least one cable retaining means in a position radially offset from the positioning means, the at least one cable retaining means being configured to releasably retain the cable, wherein the cable organiser is spoolless and in use the cable is wound around the electronic device and is releasably retained by the at least one cable retaining means.

2. The cable organiser according to claim 1, wherein the body includes a base and a cover engaged with the base.

3. The cable organiser according to claim 1, wherein the cover defines a substantially convex outer surface of the cable organiser.

4. The cable organiser of claim 2 wherein the cover is flexible.

5. The cable organiser according to claim 1, wherein the or each cable retaining means comprises a channel formation having outermost re-entrant portions defining a narrow opening through which the cable is passed to locate within the channel formation.

6. The cable organiser according to claim 1, wherein the at least one cable retaining means comprises a pair of cable retaining means.

7. The cable organiser according to claim 1, wherein at least one cable retaining means is oriented to secure the cable substantially parallel to the longitudinal axis of the jack.

8. The cable organiser according to claim 1, wherein at least one cable retaining means is connected to or integrally formed with the cover.

9. The cable organiser according to claim 1, wherein a second said cable retaining means is offset from a diametric axis of the cable organiser that crosses a position of a first said cable retaining means.

10. The cable organiser according to claim 1, wherein a first said cable retaining means is sized to receive a single cable, and a said second cable retaining means is sized to receive two cables.

11. The cable organiser according to claim 1, wherein the body includes a stabilising means for preventing rotational movement of the cable organiser relative to the electronic device when the cable organiser is mounted to the device.

12. The cable organiser according to claim 11, wherein the stabilising means includes at least one flange which when the cable organiser is mounted to the electronic device lies against an outside surface of the electronic device to prevent rotational movement of the cable organiser relative to the electronic device.

13. The cable organiser according to claim 11, wherein the stabilising means includes a pair of flanges which, when the cable organiser is mounted to the electronic device lie against opposite outside surfaces of the electronic device to prevent rotational movement of the cable organiser relative to the electronic device.

14. The cable organiser according to claim 1, wherein the cable organiser has a substantially toroidal shape.

15. The cable organiser according to of claim 1, wherein the positioning means fits around the jack with a friction fit so that the organiser remains on the jack when the jack is removed from the electronic device.

16. The cable organiser according to claim 2, wherein the cover is releasably engaged to the base.

17. A cable jack for use with an electronic device, the jack comprising:
a jack plug and a connector housing; and
the connector housing integrally formed with a cable organiser according to claim 1.

18. A cable jack for use with an electronic device, the jack comprising:
a jack plug and a connector housing; and
the connector housing integrally formed with the base of a cable organiser according to claim 2.
